(19) United States
(12) Patent Application Publication
(10) Pub. No.: US 2015/0004435 A1
(43) Pub. Date: Jan. 1, 2015

(54) METHOD FOR GROWING NON-POLAR M-PLANE EPITAXIAL LAYER OF WURTZITE SEMICONDUCTORS ON SINGLE CRYSTAL OXIDE SUBSTRATES

(71) Applicant: National Chiao Tung University, Hsinchu City (TW)

(72) Inventors: Li CHANG, Taipei County (TW); Yen-Teng HO, Tainan City (TW)

(73) Assignee: National Chiao Tung University

(21) Appl. No.: 14/322,109

(22) Filed: Jul. 2, 2014

Related U.S. Application Data
(63) Continuation-in-part of application No. 12/923,179, filed on Sep. 8, 2010.

(30) Foreign Application Priority Data
Sep. 17, 2009 (TW) 098131342

(51) Int. Cl. C30B 23/02; C30B 25/18; C30B 29/40; C30B 23/06

(52) U.S. Cl. CPC C30B 23/025; C30B 23/066; C30B 25/186; C30B 25/18; C30B 29/406
USPC 428/698; 117/101; 117/84; 117/108; 204/192.25; 117/97; 117/106

(57) ABSTRACT

The present invention relates to a method for growing a non-polar m-plane epitaxial layer on a single crystal oxide substrate, which comprises the following steps: providing a single crystal oxide with a perovskite structure; using a plane of the single crystal oxide as a substrate; and forming an m-plane epitaxial layer of wurtzite semiconductors on the plane of the single crystal oxide by a vapor deposition process, wherein the non-polar m-plane epitaxial layer may be GaN, or III-nitrides. The present invention also provides an epitaxial layer having an m-plane obtained according to the aforementioned method.

### BACKGROUND OF THE INVENTION

1. Field of the Invention

The present invention relates to a method for growing a non-polar m-plane epitaxial layer of wurtzite semiconductors on a single crystal oxide substrate and, more particularly, to a method for growing a non-polar in-plane epitaxial layer of III-nitrides, for example, GaN with the nature of both low lattice mismatch and good thermal stability. The present invention also provides an epitaxial layer having a non-polar m-plane obtained according to the aforementioned method.

2. Description of Related Art

Currently, GaN and other III-nitrides have attracted considerable interest for its successful applications on blue-to-UV light solid-state electronic devices and laser diodes. The crystal structures of these nitrides belong to a hexagonal wurtzite structure, so the crystals of these nitrides are grown along a c-axis direction [0001]. However, some studies found that a polarization effect along the c-axis may occur in c-axis GaN, due to the internal electric fields induced by the orientation of Ga and N atoms. The internal fields not only result in the shift of the valence bands and the conduction bands, but also reduce the internal quantum efficiencies of the emitting devices.

To overcome the polarization effect to increase the internal quantum efficiencies, growth of GaN or other III-nitrides in non-polar plane, such as (1-100) m-plane and (11-20) a-plane, is highly desirable. Conventional non-polar m-plane epitaxial layers of GaN are heteroepitaxially grown on m-plane SiC substrate, m-plane sapphire substrate, or (100) γ-LiAlO₂ substrate. However, large lattice mismatch may occur between the desired epitaxial layers of GaN and m-plane SiC substrate and m-plane sapphire substrate, so the grown epitaxial layers may have higher defect density, which may cause the reduction of device performance. In addition, the thermal stability of γ-LiAlO₂ substrate is poor when the growth temperature is high. Also, the small size of γ-LiAlO₂ substrate (˜1 inch) may limit its application.

Therefore, it is desirable to provide a suitable substrate for m-plane epitaxial layers of GaN or III-nitrides growth with the nature of both low lattice mismatch and good thermal stability, and a method for growing the m-plane epitaxial layer thereon.

### SUMMARY OF THE INVENTION

The object of the present invention is to provide a method for growing a non-polar m-plane epitaxial layer on a single crystal oxide substrate, to reduce the lattice mismatch between the substrate and the epitaxial layer. Also, the single crystal oxide substrate used in the method of the present invention has good thermal stability at high growth temperature, so it is suitable for the growth of the m-plane epitaxial layer of III-nitrides thereon.

Another object of the present invention is to provide a non-polar m-plane epitaxial layer, which can inhibit the shift of the valence bands and the conduction bands due to the orientation of atoms in the epitaxial layer. Hence, the problem of the decrease in internal quantum efficiencies can be solved.

To achieve the aforementioned objects, the present invention provides a method for growing a non-polar m-plane epitaxial layer on a single crystal oxide substrate, which comprises the following steps: providing a single crystal oxide with a perovskite structure; using a plane of the single crystal oxide as a substrate; and forming a non-polar m-plane epitaxial layer of wurtzite semiconductors on the substrate by a vapor deposition process.

In addition, the present invention further provides an epitaxial layer having a non-polar m-plane, which is obtained by the following steps: providing a single crystal oxide with a perovskite structure; using a plane of the single crystal oxide as a substrate; and forming a non-polar m-plane epitaxial layer on the substrate by a vapor deposition process.

In the method and the epitaxial layer of the present invention, the substrate means a growth face for forming the non-polar m-plane epitaxial layer thereon.

According to the method of the present invention, the lattice mismatch between the substrate and the non-polar m-plane epitaxial layer is smaller than that prepared in the prior art. Hence, the method of the present invention is particularly suitable for growth of the non polar m-plane layer in epitaxy. When the non-polar m-plane epitaxial layer is grown on the substrate by use of the method of the present invention, the lattice mismatch between the substrate and the non-polar m-plane epitaxial layer can be reduced to 10% or less. Furthermore, the plane of the single crystal oxide is a crystal plane or a cross section plane, and the crystal plane or the cross section plane is used as a substrate for growing the non-polar m-plane epitaxial layer. Preferably, the plane is a plane with Miller index of {112}.

According to the method and the epitaxial layer of the present invention, an oxide layer may optionally be formed on the single crystal oxide, a plane of the oxide layer is used as a substrate, and then a non-polar m-plane epitaxial layer of wurtzite semiconductors is formed on the substrate by a vapor deposition process. Herein, the compositions of the oxide layer and the single crystal oxide may be the same or different. It means the oxide layer and the single crystal oxide may be composed of the same or different compounds.

According to the method and the epitaxial layer of the present invention, the material of the single crystal oxide with the perovskite structure or the oxide layer is not particularly limited, and as long as it is a material which has good thermal stability and can inhibit the growth of other plane layers. Preferably, the single crystal oxide or the oxide layer is LaAlO₃, SrTiO₃, (La, Sr)(Al, Ta)O₃, or an LaAlO₃ alloy with a lattice constant difference of 10% or less compared to LaAlO₃. The single crystal oxide of LaAlO₃ has good thermal stability due to its high melting point of 2450K, and can also inhibit the growth of other plane layers. In addition, two inches (˜50 mm) or more of crystal faces of the single crystal oxide or the oxide layer of LaAlO₃ can be used as a substrate for the growth of the non-polar m-plane epitaxial layer, and the cost of the substrate using the single crystal oxide or the oxide layer of LaAlO₃ is lower than the conventional substrate. Hence, the substrate using the single crystal oxide or the oxide layer of LaAlO₃ can be applied in various fields.

The non-polar m-plane epitaxial layer formed according to the method of the present invention may be III-nitrides, wherein the III-nitrides may further comprise an alloy doped with Mg, Si, Ca, Sr, Ba, Cd, Zn or a combination thereof if it is necessary, for example, to faun GaN or III-V nitride semiconductors. In addition, the III-nitride may be gallium nitride, indium nitride, aluminum nitride, indium gallium nitride, aluminum gallium nitride, aluminum indium nitride, aluminum indium gallium nitride, or a combination thereof.

The method for forming the non-polar m-plane epitaxial layer on the substrate used in the present invention is not particularly limited, and can be on the substrate. Preferably, the method for growing the non-polar m-plane epitaxial layer used in the present invention is pulsed laser deposition (PLD), sputtering process, electron beam evaporation (EBE), molecular beam epitaxy (MBE), or metal-organic chemical vapor deposition (MOCVD).

The method for growing the non-polar m-plane epitaxial layer on the single crystal oxide substrate of the present invention may further comprise a step of washing the substrate with an organic solvent, before the non-polar m-plane epitaxial layer is formed on the substrate by a vapor deposition process. Herein, the type of the organic solvent is not particularly limited. Preferably, the substrate is washed with hot acetone and isopropanol.

Hence, according to the method for growing a non-polar m-plane epitaxial layer on a single crystal oxide substrate of the present invention, a substrate, which has good thermal stability at high temperature and low lattice mismatch between the substrate and the epitaxial layer, is selected for the growth of a m-plane epitaxial layer of III-nitrides. In addition, the non-polar m-plane epitaxial layer obtained by the aforementioned method can inhibit the polarization effect resulting from the orientation of atoms in the epitaxial layer. Hence, the shift of the valence bands and the conduction bands can be reduced, and the internal quantum efficiencies of emitting devices can be improved when the epitaxial layer obtained by the method of the present invention is used.

### BRIEF DESCRIPTION OF THE DRAWINGS

FIG. 1 is a perspective view showing the growth of a non-polar m-plane epitaxial layer of GaN in a preferred embodiment of the present invention;

FIGS. 2 are X-ray diffraction patterns of non-polar m-plane epitaxial layer of GaN in a preferred embodiment of the present invention;

FIG. 3(a) is an atomic configuration of a {112} plane of LaAlO₃ single crystal oxide in a preferred embodiment of the present invention; and

FIG. 3(b) is an atomic configuration of an epitaxial m-plane {1100} GaN in a preferred embodiment of the present invention.

### DETAILED DESCRIPTION OF THE PREFERRED EMBODIMENT

The present provides a method for growing a non-polar m-plane epitaxial layer on a single crystal oxide substrate and a non-polar m-plane epitaxial layer obtained by the same. The method comprises the following steps: providing a single crystal oxide with a perovskite structure; using a plane of the single crystal oxide as a substrate; and forming a non-polar m-plane epitaxial layer of wurtzite semiconductors on the substrate by a vapor deposition process.

Hereafter, the method for growing a non-polar m-plane epitaxial layer on a single crystal oxide substrate of the present invention is described in detail.

### Embodiment 1

First, a single crystal oxide with a perovskite structure is provided, wherein the material of the single crystal oxide with the perovskite structure is not particularly limited, and as long as it is a material which has good thermal stability and can inhibit the growth of other interface layers. Preferably, the single crystal oxide or the oxide layer is LaAlO₃, SrTiO₃, (LaSr)(AlTa)O₃, or an LaAlO₃ alloy with a lattice constant difference of 10% or less compared to LaAlO₃. In the present embodiment, a 2-inch (˜50 mm) sized LaAlO₃ single crystal oxide was used.

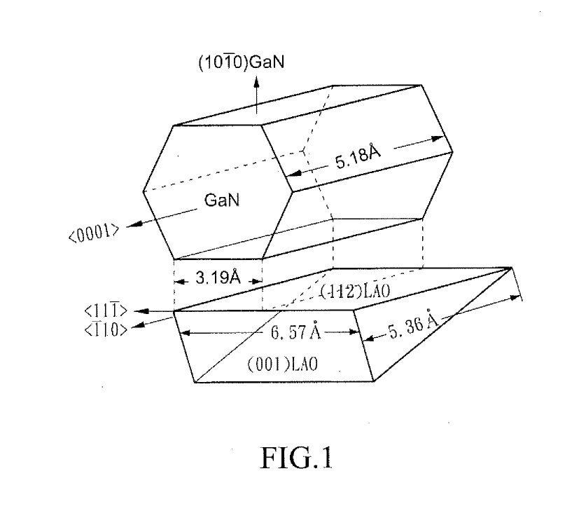

Then, a crystal plane or a cross section plane of the LaAlO₃ single crystal oxide is used as a substrate, as shown in FIG. 1, which is a perspective view showing the growth of a non-polar m-plane epitaxial layer in the present embodiment. In the present embodiment, the plane with Miller index of {112} was used as a substrate. Then, the substrate was loaded into a chamber, washed with hot acetone and isopropanol, heated at over 850° C. in high vacuum for 1 hour to remove impurities on the substrate. Additional preparation of substrate may involve pre-treating the substrate with a hydrogen gas (H₂) purge in a vacuum environment at a temperature of around 800-1000° C.

An epitaxial m-plane {1100} GaN layer was grown on the substrate in a Metal Organic Chemical Vapor Deposition (MOCVD) system at a temperature of around 900-1000° C. by Al precursor Trimethylgallium (referred to as TMGa or (CH₃)₃Ga) and nitrogen precursor Ammonia (NH₃) Then, an epitaxial m-plane {1100} GaN layer was deposited on the substrate, as shown in FIG. 1.

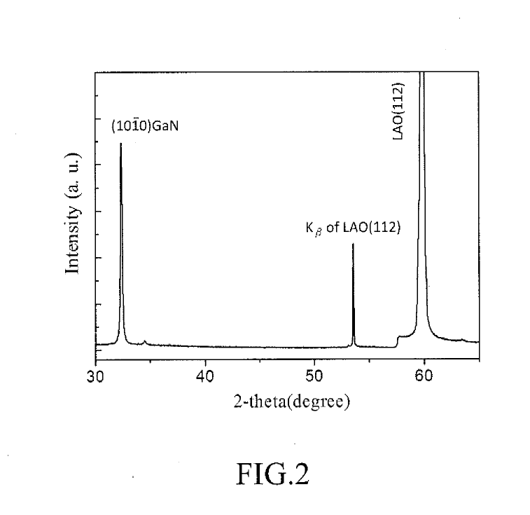

FIG. 2 is x-ray diffraction patterns of non-polar m-plane epitaxial layer of GaN in the present embodiment. According to the data shown in FIG. 2 the m-plane GaN epitaxial layer was grown on the (112) LaAlO₃ single crystal oxide in the present embodiment.

### Embodiment 2

The substrate materials and the m-plane GaN epitaxial layer mentioned in the present embodiment are the same as those in Embodiment 1, except that the growth method is pulsed laser deposition (PLD). The ablation target used in PLD is a III-nitride, such as GaN. The ablation source of KrF excimer laser with wavelength of 248 nm or 193 nm were used to grow. In the present embodiment, an epitaxial layer of III nitride, i.e. a GaN epitaxial layer, was obtained. The functions and the applications of the non-polar m-plane epitaxial layer of III nitride (GaN) grown in the present embodiment are the same as those of the epitaxial layer of GaN grown in Embodiment 1.

Though only GaN was used as an ablation target in the present embodiment, other III-nitrides, such as indium nitride, aluminum nitride, indium gallium nitride, aluminum gallium nitride, aluminum indium nitride, aluminum indium gallium nitride, or a combination thereof, can also be used as an ablation target for growth of an epitaxial layer through the same method described in Embodiment 1. Also, the epitaxial layer formed by other III-nitrides has the same functions and applications as those of the epitaxial layer of ZnO grown in Embodiment 1.

### Embodiment 3

The materials and method used in the present embodiment are the same as those in Embodiment 1 or 2, except that an oxide layer (not shown in the figure) was formed on the single crystal oxide, and a plane of the oxide layer was used as a substrate.

In the present embodiment, an SrTiO₃ single crystal oxide with a perovskite structure was provided, and then an LaAlO₃ oxide layer was formed on the SrTiO₃ single crystal oxide. A plane of the LaAlO₃ oxide layer with Miller Index of {112} was used as a substrate, and a non-polar m-plane epitaxial layer of wurtzite semiconductors was formed on the substrate through a vapor deposition process with the same deposition conditions as described in Embodiment 1. Though the SrTiO₃ single crystal oxide and the LaAlO₃ oxide layer were exemplified in the present embodiment, the compositions of the oxide layer and the single crystal oxide can be the same or different if it is needed. Also, the functions and applications of the epitaxial layer obtained in the present embodiment are the same as those of the epitaxial layer grown in Embodiment 1 or 2.

### Experimental Example 1

In the present experimental example, the lattice mismatch between the non-polar m-plane GaN epitaxial layer obtained in Embodiment 1 and the plane of the {112} LaAlO₃ single crystal oxide used as a substrate is described in detail.

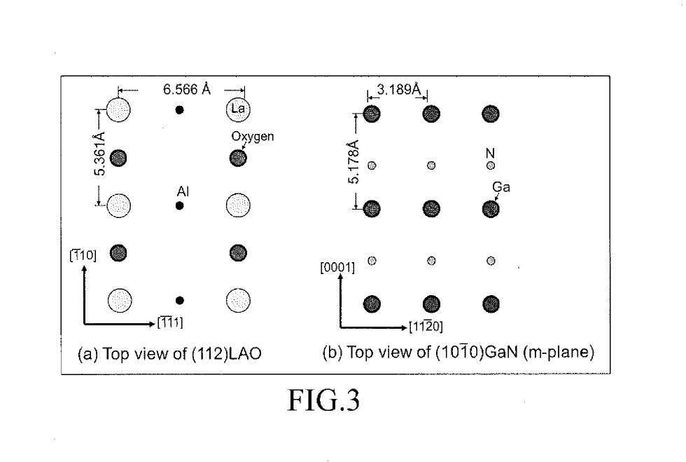

FIG. 3(a) is an atomic configuration of a plane of {112} LaAlO₃ single crystal oxide, and FIG. 3(b) is an atomic configuration of a non-polar m-plane {1 1̅00} GaN layer which can be in epitaxy, wherein the lattice mismatch between them is less than 4%. According to FIG. 3(a), the distance between oxygen atoms in the plane of {112} LaAlO₃ single crystal oxide is 5.360 Å and 6.566 Å respectively. According to FIG. 3(b), the distance between oxygen atoms in the non-polar m-plane {1 1̅00} GaN epitaxial layer is 5.178 Å and 3.189 Å respectively. After calculation, the lattice mismatch between the non-polar m-plane {1 1̅00} GaN epitaxial layer and the plane of {112} LaAlO₃ single crystal oxide is estimated to be −3.39% along the direction parallel to the c-axis of GaN ((5.178-5.360)/5.360=−3.39%), and −1.0% perpendicular to the c-axis ((3.189×2−6.566)/6.566=−2.86%). Compared to the conventional substrate, the lattice mismatch between the substrate and the epitaxial layer of the present invention is low. In addition, the substrate used in the present invention has good thermal stability at high temperature, and is suitable for the growth of m-plane epitaxial layers of GaN or III-nitrides.

In conclusion, according to the method for growing a non-polar m-plane epitaxial layer on a single crystal oxide substrate of the present invention, a substrate, which has good thermal stability at high temperature and low lattice mismatch between the substrate and the epitaxial layer, is selected for the growth of an m-plane epitaxial layer of GaN or III-nitrides. In addition, the non-polar m-plane epitaxial layer obtained by the aforementioned method can inhibit the polarization effect resulting from the orientation of atoms in the epitaxial layer. Hence, the shift of the valence bands and the conduction bands can be reduced, and the internal quantum efficiencies of emitting devices can be improved.

Therefore, when the epitaxial layer obtained by the method of the present invention is applied to blue-to-UV light solid-state electronic devices and laser diodes, the polarization effect can be eliminated and the internal quantum efficiencies can be increased, so that the light-emitting efficiencies of the emitting devices can be improved greatly.

Although the present invention has been explained in relation to its preferred embodiment, it is to be understood that many other possible modifications and variations can be made without departing from the scope of the invention as hereinafter claimed.

1. A method for growing a non-polar m-plane epitaxial layer on a single crystal oxide substrate, comprising the following steps:
providing a single crystal oxide with a perovskite structure;
using a plane of the single crystal oxide as a substrate; and
forming a non-polar m-plane epitaxial layer of wurtzite semiconductors on the substrate by a vapor deposition process,
wherein the non-polar m-plane epitaxial layer is III-nitrides.

2. The method as claimed in claim 1, further comprising the following steps:
forming an oxide layer on the single crystal oxide;
using a plane of the oxide layer as a substrate; and
forming a non-polar m-plane epitaxial layer of wurtzite semiconductors on the substrate by a vapor deposition process,
wherein, the compositions of the oxide layer and the single crystal oxide are the same or different.

3. The method as claimed in claim 1, wherein the lattice mismatch between the substrate and the non-polar m-plane epitaxial layer is 10% or less.

4. The method as claimed in claim 1, wherein the single crystal oxide is LaAlO₃, SrTiO₃, (La, Sr)(Al, Ta)O₃, or an LaAlO₃ alloy with a lattice constant difference of 10% or less compared to LaAlO₃.

5. The method as claimed in claim 1, wherein the III nitride is gallium nitride, indium nitride, aluminum nitride, indium gallium nitride, aluminum gallium nitride, aluminum indium nitride, aluminum indium gallium nitride, or a combination thereof.

6. The method as claimed in claim 1, wherein the III nitride further comprises: an alloy doped with Mg, Si, Ca, Sr, Ba, Cd, Zn or a combination thereof.

7. The method as claimed in claim 1, wherein the plane is a crystal plane, or a cross section plane.

8. The method as claimed in claim 1, wherein the plane is a plane with Miller index of {112}.

9. The method as claimed in claim 1, wherein the vapor deposition process is physical vapor deposition (PVD) or chemical vapor deposition (CVD), which comprises pulsed laser deposition (PLD), sputtering process, electron beam evaporation (EBE), molecular beam epitaxy, or metal-organic chemical vapor deposition (MOCVD).

10. The method as claimed in claim 1, further comprising a step of washing the substrate with hot acetone and isopropanol, before the non-polar m-plane epitaxial layer is formed on the substrate by a vapor deposition process.

11. An epitaxial layer having a non-polar m-plane, which is obtained by the following steps comprising:
providing a single crystal oxide with a perovskite structure;
using a plane of the single crystal oxide as a substrate; and
forming a non-polar m-plane epitaxial layer of wurtzite semiconductors on the substrate by a vapor deposition process,
wherein the non-polar m-plane epitaxial layer is Ill-nitrides.

12. The epitaxial layer having a non-polar m-plane as claimed in claim 11, further comprising the following steps:
forming an oxide layer on the single crystal oxide;
using a plane of the oxide layer as a substrate; and
forming a non-polar m-plane epitaxial layer of wurtzite semiconductors on the substrate by a vapor deposition process,
wherein, the compositions of the oxide layer and the single crystal oxide are the same or different.

13. The epitaxial layer having a non-polar m-plane as claimed in claim 11, wherein the lattice mismatch between the substrate and the non-polar m-plane epitaxial layer is 10% or less.

14. The epitaxial layer having a non-polar m-plane as claimed in claim 11, wherein the single crystal oxide is LaAlO₃, SrTiO₃, (La,Sr)(Al,Ta)O₃, or an LaAlO₃ alloy with a lattice constant difference of 10% or less compared to LaAlO₃.

15. The epitaxial layer having a non-polar m-plane as claimed in claim 11, wherein the Ill nitride is gallium nitride, indium nitride, aluminum nitride, indium gallium nitride, aluminum gallium nitride, aluminum indium nitride, aluminum indium gallium nitride, or a combination thereof.

16. The epitaxial layer having a non-polar m-plane as claimed in claim 11, wherein the III-nitrides further comprises: an alloy doped with Mg, Si, Ca, Sr, Ba, Cd, Zn or a combination thereof.

17. The epitaxial layer having a non-polar m-plane as claimed in claim 11, wherein the plane is a crystal plane, or a cross section plane.

18. The epitaxial layer having a non-polar m-plane as claimed in claim 11, wherein the plane is a plane with Miller index of {112}.

19. The epitaxial layer having a non-polar m-plane as claimed in claim 11, wherein the vapor deposition process is physical vapor deposition (PVD) or chemical vapor deposition (CVD), which comprises pulsed laser deposition (PLD), sputtering process, electron beam evaporation (EBE), molecular beam epitaxy, or metal-organic chemical vapor deposition (MOCVD).

20. The epitaxial layer having a non-polar m-plane as claimed in claim 11, further comprising a step of washing the substrate with hot acetone and isopropanol, before the non-polar m-plane epitaxial layer is formed on the substrate by a vapor deposition process.
